(19) United States
(12) Patent Application Publication
(10) Pub. No.: US 2016/0264342 A1
(43) Pub. Date: Sep. 15, 2016

(54) MASKING USING IN-MOLD DECORATION

(71) Applicant: GOJO Industries, Inc., Akron, OH (US)

(72) Inventor: Shelby Jay Buell, Medina, OH (US)

(21) Appl. No.: 15/064,828

(22) Filed: Mar. 9, 2016

Related U.S. Application Data
(60) Provisional application No. 62/130,225, filed on Mar. 9, 2015.

(51) Int. Cl. B65D 83/00; C23C 16/44

(52) U.S. Cl. CPC B65D 83/00; C23C 16/44

(57) ABSTRACT

Among other things, one or more systems and/or methods of forming a device housing, such as a hygiene device housing of a hygiene device, are described herein. An in-mold decoration (IMD), comprising an adhesive layer between an outer layer (e.g., a sacrificial layer) and an aesthetic layer (e.g., a layer comprising color, a design, a logo, a shielding material, etc.) is formed. A device housing is formed to comprise the IMD, such as through a molding process. A metallic layer is deposited over the device housing. The device housing is exposed to an energy emission to disrupt the adhesive layer, such as to remove a bonding property of the adhesive layer. The disruption of the adhesive layer may remove the outer layer and a portion of the metallic layer overlaying the outer layer, thus exposing the aesthetic layer such as a design of the aesthetic layer for the hygiene device.

### CROSS-REFERENCE TO RELATED APPLICATIONS

This application claims priority to U.S. Provisional Patent Application No. 62/130,225, filed on Mar. 9, 2015, the entire disclosure of which is hereby incorporated by reference,

### TECHNICAL FIELD

The instant application is generally directed towards a hygiene device housing, comprising an aesthetic layer, for a device. In particular, the hygiene device housing for a hygiene device (e.g., a material dispenser that dispenses a material such as soap, sanitizer, paper towels, etc.) is formed to comprise the aesthetic layer (e.g., a logo, a transparent layer, a shielding layer, etc.) and a metallic layer.

### BACKGROUND

Many locations, such as hospitals, businesses, homes, restaurants, etc., utilize hygiene devices for hygiene, such as dispensers to dispense material or other bathroom devices for hygiene. For example, a dispenser may dispense a liquid material, a powder material, an aerosol material, paper towels, and/or other materials (e.g., soap, anti-bacterial gels, cleansers, disinfectants, lotions, etc.). Some dispensers utilize a refill container for ease of maintenance, environmental concerns, etc. The refill container may, for example, comprise a pump and/or nozzle mechanism that can be used by a dispenser to dispense material from the refill container. People and/or businesses may desire customized hygiene devices that may have a particular look, such as a company logo, a color, a transparency where material within a refill container may be visible, an electromagnetic or radio frequency shielding layer, etc. However, customization of dispenser systems may be costly due to fabrication costs (e.g., a cost associated with designing a custom mask used to define a custom design region on a device housing), thus prohibiting people and/or businesses from purchasing a custom dispenser system.

### SUMMARY

According to an embodiment, a method of hygiene device housing formation comprises forming a device housing. The device housing may comprise a shaped in-mold decoration (IMD). The shaped IMD may comprise an adhesive layer between an outer layer and an aesthetic layer of the shaped IMD. A metallic layer may be deposited over the device housing. The device housing may be exposed to an energy emission to disrupt the adhesive layer, such as to remove a bonding property of the adhesive layer, to remove the outer layer so that the aesthetic layer is exposed and visible.

According to an embodiment, a method of forming a hygiene device housing may comprise shaping an in-mold decoration (IMD) to form a shaped IMD. The device housing may be formed to comprise the shaped IMD. The shaped IMD may comprise an adhesive layer between an outer layer and an aesthetic layer of the shaped IMD. A metallic layer may be deposited over the device housing. The device housing may be exposed to an energy emission to disrupt the adhesive layer to remove the outer layer exposing the aesthetic layer and to form the hygiene device housing.

According to an embodiment, a hygiene device may comprise a hygiene device housing. The hygiene device housing may comprise an aesthetic layer that comprises a transparent layer, a logo layer, a text layer, a graphics layer, a colored layer, and/or a shielding layer. The hygiene device housing may comprise a metallic layer formed over a first portion of the hygiene device house. The first portion may not comprise the aesthetic layer. The metallic layer may comprise a first top surface along a first side of the hygiene device house. The aesthetic layer may comprise a second top surface along the first side. The first top surface has a first distance from a second side of the hygiene device housing. The second top surface has a second distance from the second side. The first side is opposite the second side. The first distance is greater than the second distance.

### BRIEF DESCRIPTION OF THE DRAWINGS

The embodiments set forth in the drawings are illustrative and exemplary in nature and not intended to limit the subject matter defined by the claims. The following description of the illustrative embodiments can be understood when read in conjunction with the following drawings.

FIG. 1 is an illustration of an example dispensing device, according to some embodiments.

FIG. 2A is an illustration an in-mold decoration (IMD), according to some embodiments.

FIG. 2B is an illustration of an adhesive layer, according to some embodiments.

FIG. 2C is an illustration of a shaped in-mold decoration (IMD), according to some embodiments.

FIG. 2D is an illustration of a device housing, according to some embodiments.

FIG. 2E is an illustration of a deposition of a metallic layer and an exposure to an energy emission, according to some embodiments.

FIG. 2F is an illustration of a device housing, according to some embodiments.

FIG. 3 is an illustration of an example method of device housing, according to some embodiments.

FIG. 4 is an illustration of a hygiene device having a logo, according to some embodiments.

FIG. 5 is an illustration of a hygiene device having a first aesthetic layer and a second aesthetic layer, according to some embodiments.

FIG. 6 is an illustration of a hygiene device having a transparent aesthetic layer, according to some embodiments.

FIG. 7 is an illustration of a hygiene device having a triangular aesthetic layer, according to some embodiments.

FIG. 8 is an illustration of a hygiene device having a central oblong aesthetic layer, according to some embodiments.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide an understanding of the claimed subject matter. It is evident, however, that the claimed subject matter can be practiced without these specific details. In other instances, structures and devices are illustrated in block diagram form in order to facilitate describing the claimed subject matter.

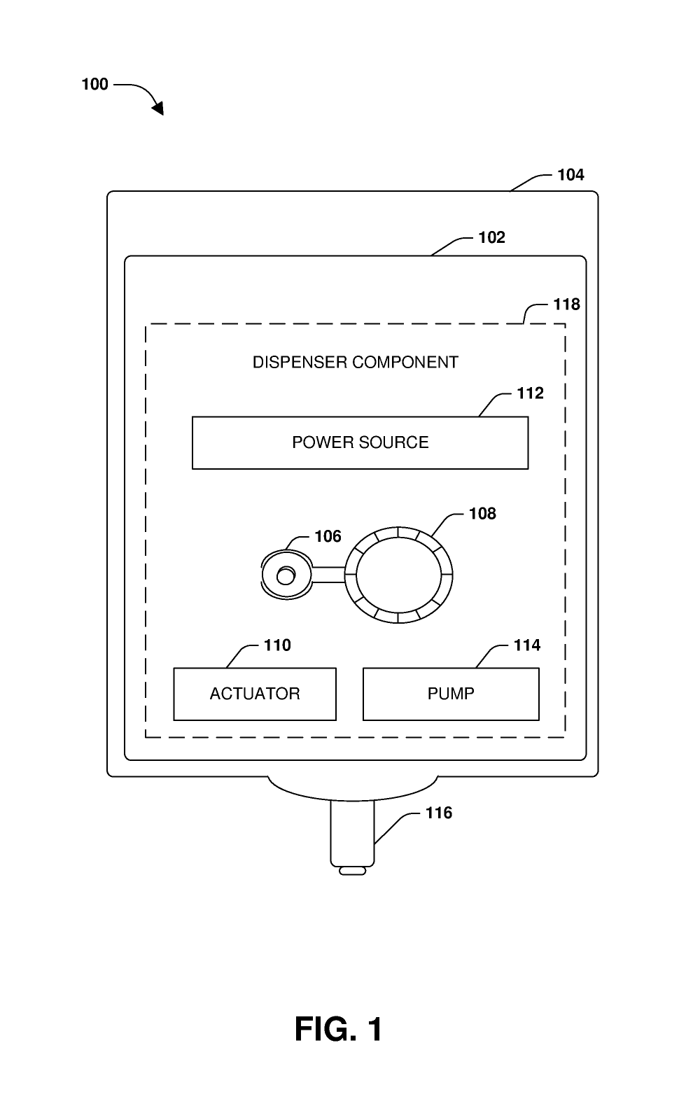

FIG. 1 illustrates an example of a dispensing system 100 comprising a dispensing device 104. The dispensing device 104 (e.g., a hygiene device) may comprise a device housing 102 (e.g., a hygiene device housing) configured to hold a material container comprising a material (e.g., a liquid material, a powder material, an aerosol material, an antibacterial product, paper towels, medicine, etc.). The device housing 102 may contain various mechanical and/or electrical components that facilitate operation of the dispensing device 104, such as one or more components that dispense material from the material container. In an example, the device housing 102 may contain a dispenser component 118. The dispenser component 118 may comprise an actuator 110, a power source 112, a motor 106, a drivetrain 108 (e.g., a gear train), and/or other components (e.g., a pump 114 and/or a dispenser nozzle 116 associated with the material container). The power source 112 (e.g., a battery, an AC adapter, power from a powered network communication line, etc.) may provide power to the actuator 110, the motor 106, and/or other components. The actuator 110 may be configured to detect a dispense request. The actuator 110 may be configured to invoke the motor 106 to operate the drivetrain 108 so that the pump 114 dispenses material from the material container through the dispenser nozzle 116 (e.g., responsive to the dispense request).

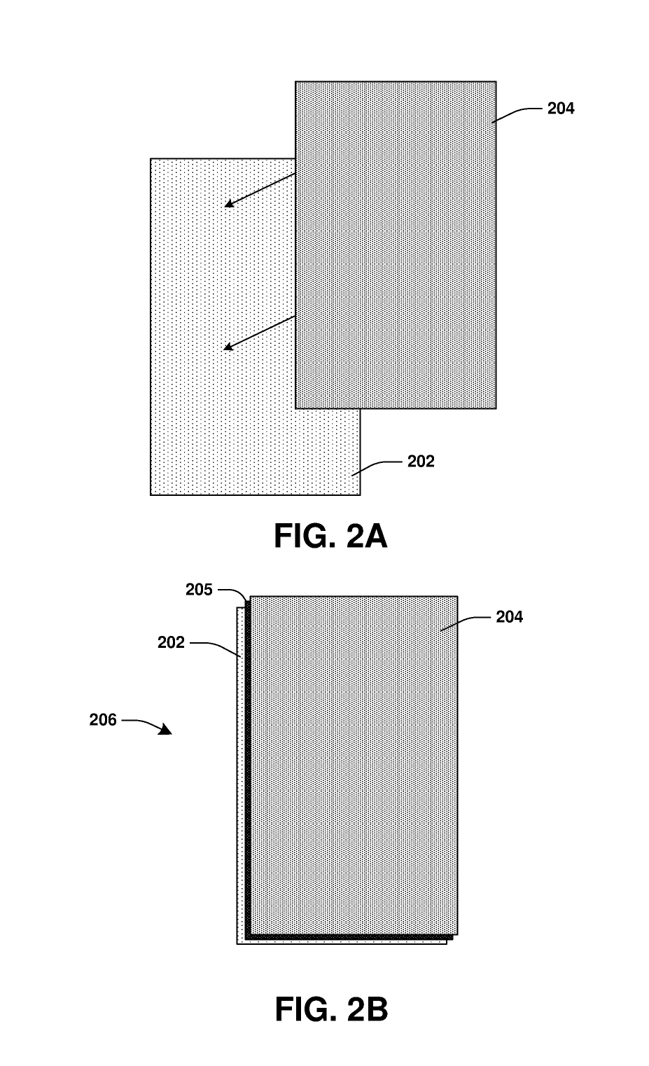

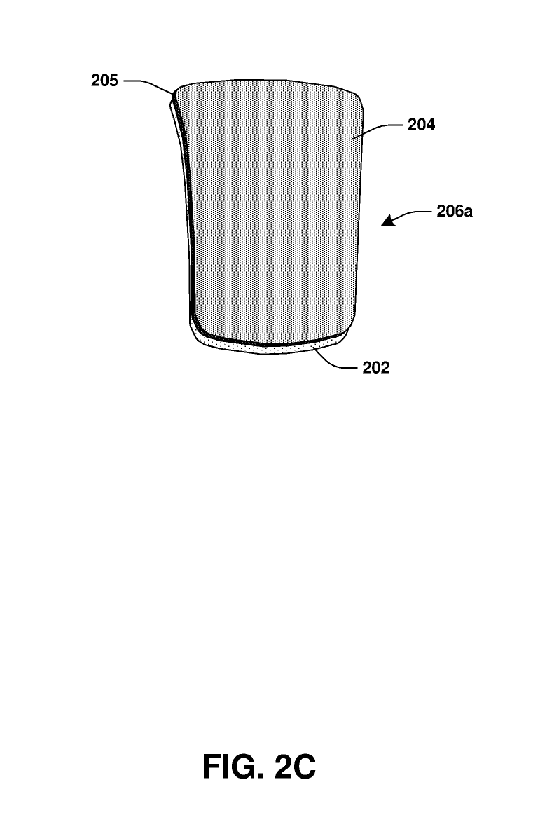

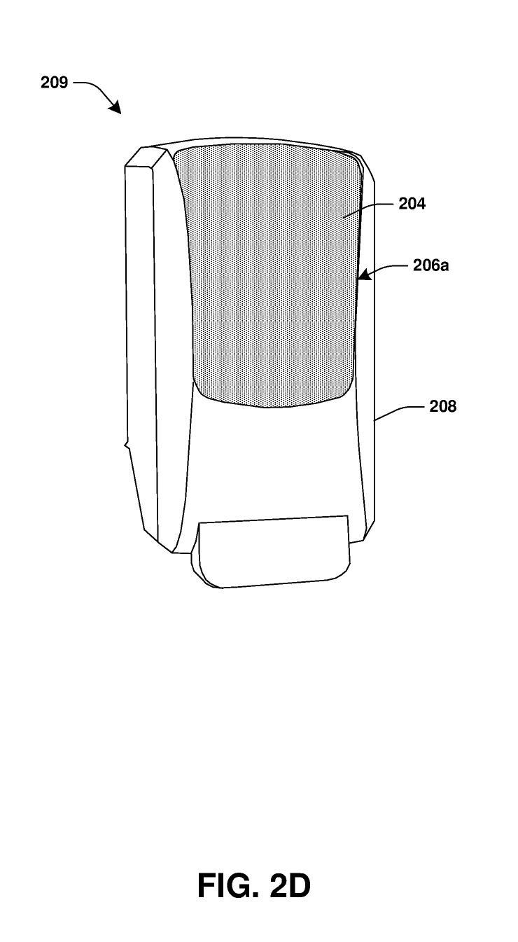

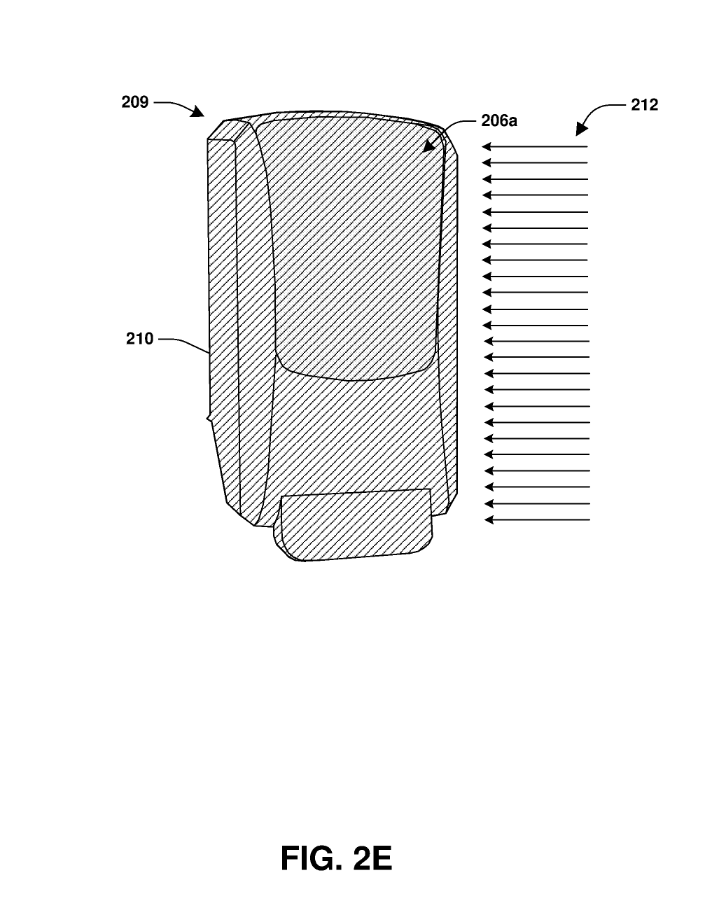

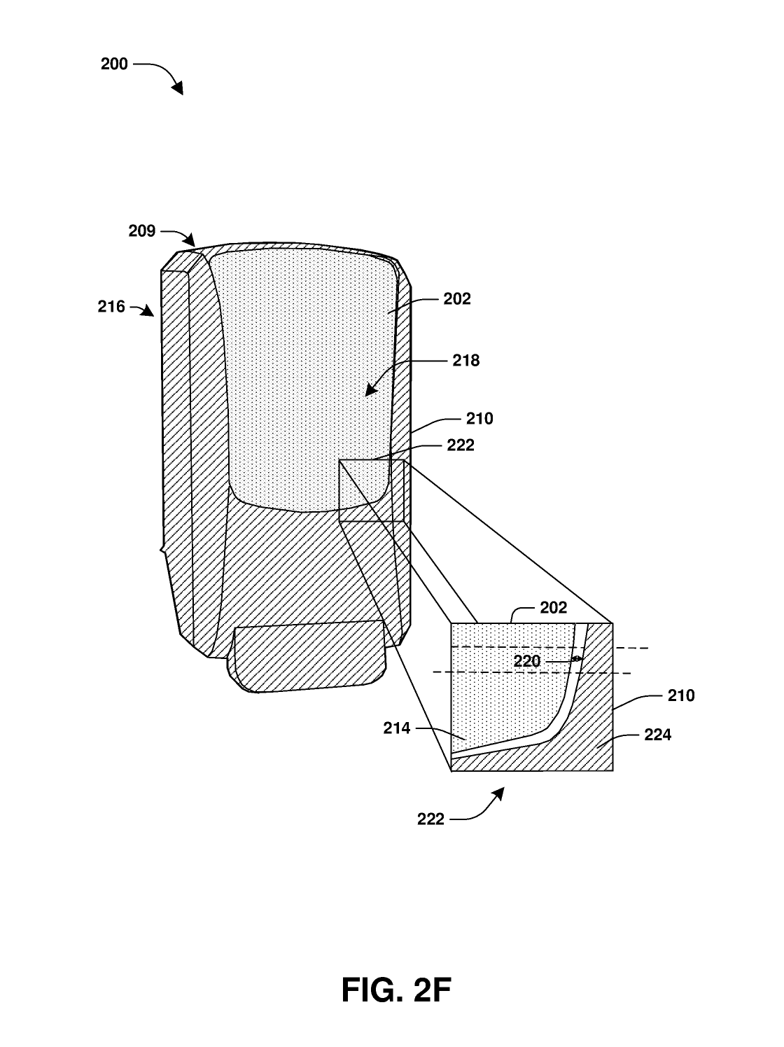

FIGS. 2A-2F illustrate a formation of a hygiene device housing 200 of a hygiene device, comprising a device housing component 208, a metallic layer 210 and/or an in-mold decoration (IMD) 206. FIG. 2A illustrates an outer layer 204 (e.g., a sacrificial layer) that is to be combined with an aesthetic layer 202 to form the IMD 206, as illustrated in FIG. 2B. The outer layer 204 and the aesthetic layer 202 may comprise different materials. The aesthetic layer 202 may comprise one or more layers of plastic and/or composite material. In an example, the aesthetic layer 202 may comprise one or more layers, such as a first layer and a second layer. A first design (e.g., a company logo, text, a picture etc.) may be formed on the first layer and/or a second design (e.g., a color) may be formed on the second layer. The aesthetic layer 202 may be clear/transparent or may comprise one or more colors. The aesthetic layer 202 may comprise a polyester material or other material that may be compatible with a device housing material of the device housing component 208 (e.g., a material that will bond, but not mix and/or combine, with the device house material of the device housing component 208, because mixing and/or combining may inhibit removal of the outer layer 204 from the aesthetic layer 202). The aesthetic layer 202 may comprise an aesthetic layer thickness between about 1 μm to about 900 μm.

The outer layer 204 may comprise one or more layers of plastic and/or composite material. The outer layer 204 may comprise polypropylene, a varnish, and/or a material that may be compatible with the device housing material of the device housing component 208. The outer layer 204 may comprise an outer layer thickness between about 1 μm to about 700 μm. In an example, the outer layer 204 may be a sacrificial layer that may be removed from the hygiene device housing 200 during fabrication of the hygiene device housing 200.

FIG. 2B illustrates an example of forming the adhesive layer 205 between the outer layer 204 and the aesthetic layer 202 to form the IMD 206. The adhesive layer 205 may comprise a bond (e.g., a molecular bond) between the aesthetic layer 202 and the outer layer 204. The adhesive layer 205 may be formed by an application of thermal energy, electromagnetic radiation, etc.

FIG. 2C illustrates an example of shaping the IMD 206 to form a shaped IMD 206a. The shaped IMD 206a may be formed by cutting (e.g., using a dye cut) the IMD 206 into a desired form and/or shape. The shaped IMD 206a may be placed in a molding chamber (e.g., an injection molding chamber) using static electricity. The shaped IMD 206a may be placed in a position that reflects a desired placement of the shaped IMD relative to the device housing component 208 in a device housing 209, illustrated in FIG. 2D. A strip of composite material may be formed along a perimeter edge of the shaped IMD 206a. The strip may have a thickness greater than the outer layer thickness of the outer layer 204 and/or the aesthetic layer thickness of the aesthetic layer 202. The strip may comprise a material that is the same or different than the outer layer 204. It may be appreciated that the shaped IMD 206a may be formed to have any shape and/or size.

FIG. 2D illustrates an example of forming the device housing 209. The device housing 209 may comprise the shaped IMD 206a and the device housing component 208. The device housing 209 may be formed using the molding chamber. The device housing 209 may be formed using injection molding, blow molding, and/or some other type of molding. The composite housing 209 may be formed by injecting a molten plastic (e.g., a molten ABS, a molten nylon, a plastic resin, some other plastic, etc.) into the molding chamber. In an example, the shaped IMD 206a may be positioned within the molding chamber, and device housing material may be injected into the molding chamber to form the device housing component 208 around the shaped IMD 206a, thus resulting in the device housing 209.

FIG. 2E illustrates an example of depositing a metallic layer 210 over the device housing 209. The deposition may comprise physical vapor deposition (PVD) and/or vacuum metal deposition (e.g., a thin film of material may be evaporated onto the device housing 209). The deposition may occur in a deposition chamber. The deposition chamber may be a same or different chamber as the molding chamber. The metallic layer 210 may have a metallic layer thickness between about 2 μm to about 7 μm. The metallic layer 210 may comprise a metal, an alloy, and/or a compound. The metallic layer 210 may comprise aluminum, copper, bright chrome, stainless steel, nickel chrome, etc.

The device housing 209, comprising the metallic layer 210, may be exposed to an energy emission 212. The energy emission 212 may disrupt the adhesive layer 205 of the shaped IMD 206a, such as to remove a bonding property of the adhesive layer 205, in order to remove the outer layer 204 and a portion of the metal layer 210 overlaying the outer layer 204 from the device housing 209, thus exposing the aesthetic layer 202. The energy emission 212 may comprise ultra violet light, electromagnetic radiation, an electromagnetic field, and/or thermal energy. A clear coat may be applied before and/or after the device housing 209 is exposed to the energy emission 212. For example, if the clear coat is applied before the exposing, then a curing of the clear coat (e.g., exposing the clear coat to ultra violet radiation) may disrupt the adhesive layer 205, thus removing the outer layer 204 and the portion of the metal layer 210 overlaying the outer layer 204 from the device housing 209.

FIG. 2F illustrates the hygiene device housing 200 after the outer layer 204 and the portion of the metallic layer 210 overlaying the outer layer 204 are removed from the device housing 209 to expose the aesthetic layer 202. The removal of the outer layer 204 may result in the aesthetic layer 202, such as a design, logo, transparent portion, color, or other portion of the aesthetic layer 202, being visible. In an example, the strip of composite material, which was formed along the perimeter edge of the shaped IMD 206a, may be removed to create clean (e.g., well defined) edges between the aesthetic layer 202 and the metallic layer 210.

A zoomed in region 222 illustrates a zoomed in view of a portion of the hygiene device housing 200 that includes the aesthetic layer 202 and the metallic layer 210 that is formed over the device housing 209. The metallic layer 210 may have a first top surface 224 along a first side 218 of the hygiene device housing 200. The aesthetic layer 202 may have a second top surface 214 along the first side 218. The first side 218 may be opposite a second side 216 of the hygiene device housing 200 (e.g., if the first side 218 is a front side of the hygiene device housing 200, then the second side 216 may be a back side of the hygiene device housing 200). The first top surface 224 may be a first distance from the second side 216 of the hygiene device housing 200. The second top surface 214 may be a second distance from the second side 216 of the hygiene device housing 200. The first distance may be greater than the second distance. A distance difference 220 between the first distance and the second distance may be from about 0.05 cm to about 1 cm.

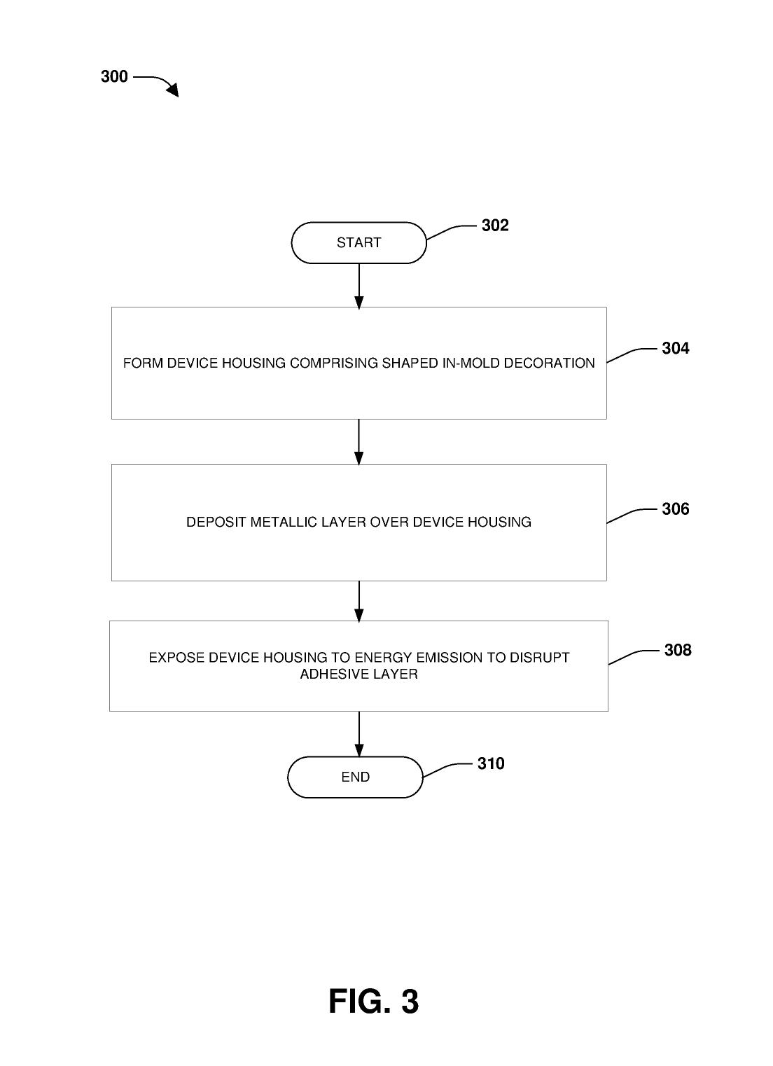

FIG. 3 illustrates a method 300 of device housing formation. At 302 the method 300 starts. At 304, a device housing, comprising a shaped in-mold decoration (IMD), may be formed. The shaped IMD may comprise an adhesive layer between an outer layer and an aesthetic layer (e.g., the aesthetic layer may comprise a color, a design, a logo, etc.) of the shaped IMD. In an example, an IMD may be shaped, such as cut, to form the shaped IMD.

At 306, a metallic layer may be deposited over the device housing (e.g., using physical vapor deposition, vacuum metal deposition, etc.). The metallic layer may comprise a metal, a metal alloy, etc. At 308, the device housing, such as the metallic layer overlaying the device housing, may be exposed to an energy emission (e.g., ultra violet light, electromagnetic radiation, electromagnetic field, thermal energy, etc.) that disrupts the adhesive layer to remove the outer layer, thus exposing the aesthetic layer. A clear coat may be applied to the device housing. At 310, the method 300 ends.

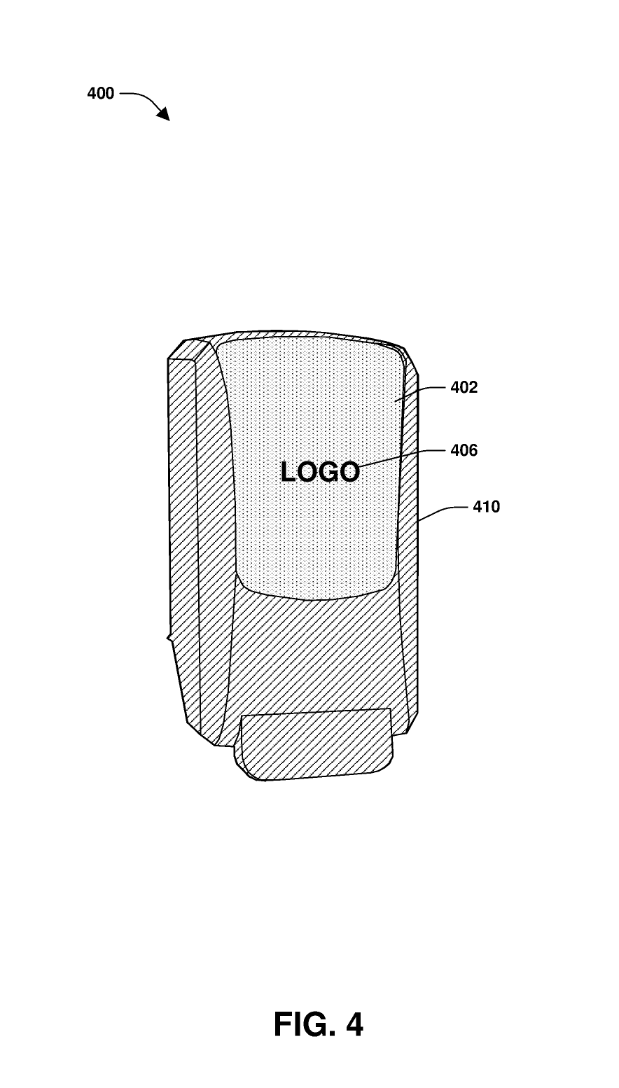

FIG. 4 illustrates a hygiene device housing 400 comprising an aesthetic layer 402 comprising a logo 406. The hygiene device housing 400 may comprise a metallic layer 410 overlaying a first portion of the hygiene device housing 400 (e.g., a hygiene device component of the hygiene device housing 400). The first portion may not comprise the aesthetic layer 402.

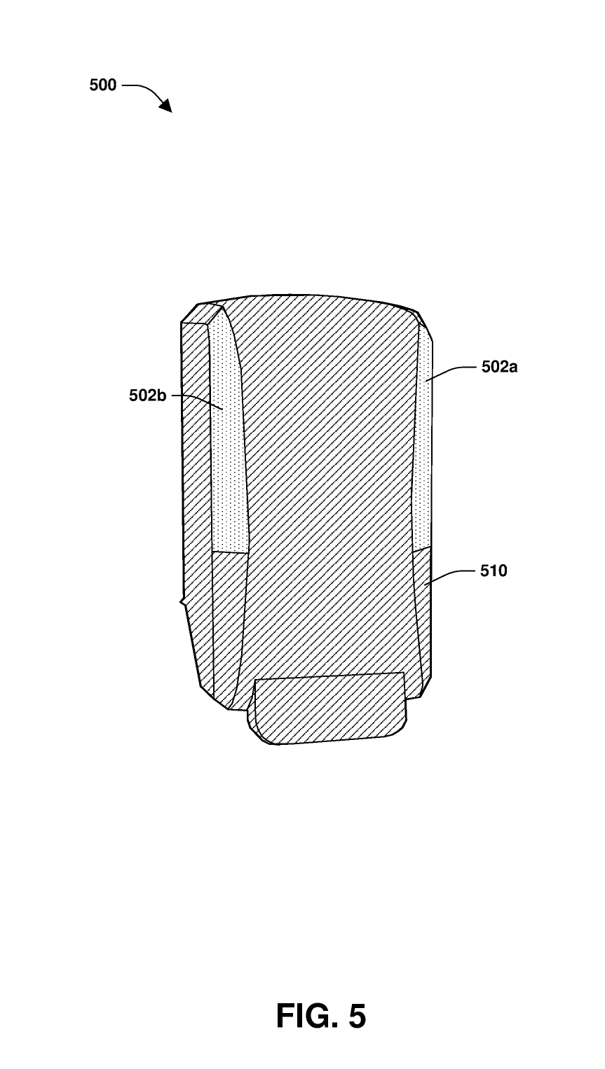

FIG. 5 illustrates a hygiene device housing 500 comprising a first aesthetic layer 502a and a second aesthetic layer 502b. The hygiene device housing 500 may comprise a metallic layer 510 overlaying a first portion of the hygiene device housing 500. The first portion may not comprise the first aesthetic layer 502a and/or the second aesthetic layer 502b.

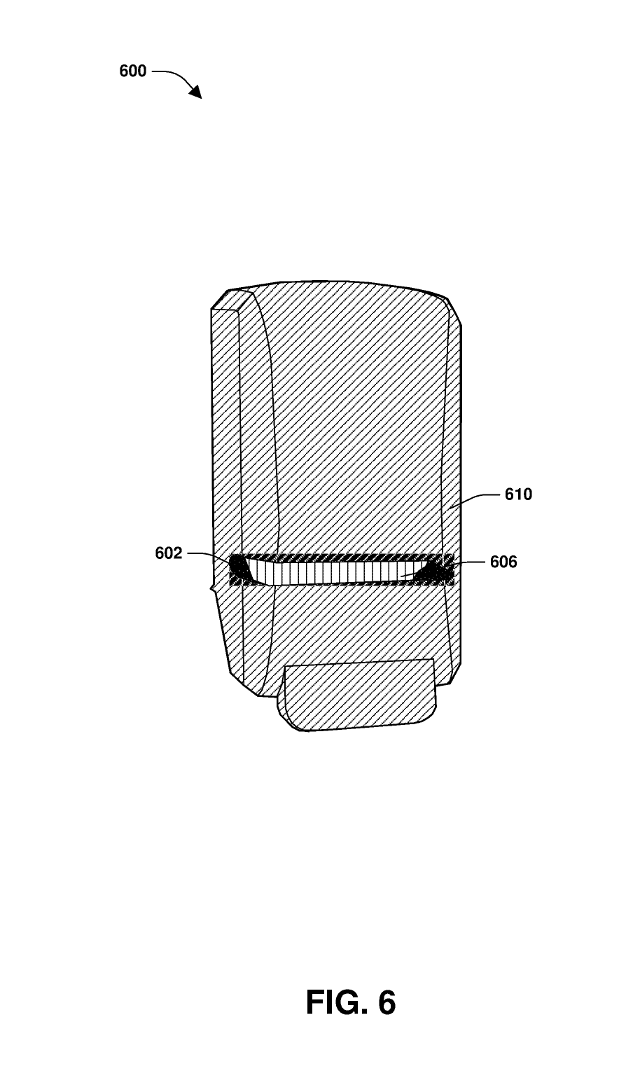

FIG. 6 illustrates a hygiene device housing 600 comprising a transparent aesthetic layer 602. The hygiene device housing 600 comprises a metallic layer 610 overlaying a first portion of the hygiene device housing 600. The first portion may not comprise the transparent aesthetic layer 602. A material 606 (e.g., soap, a disinfectant liquid, etc.) may be visible through the transparent aesthetic layer 602.

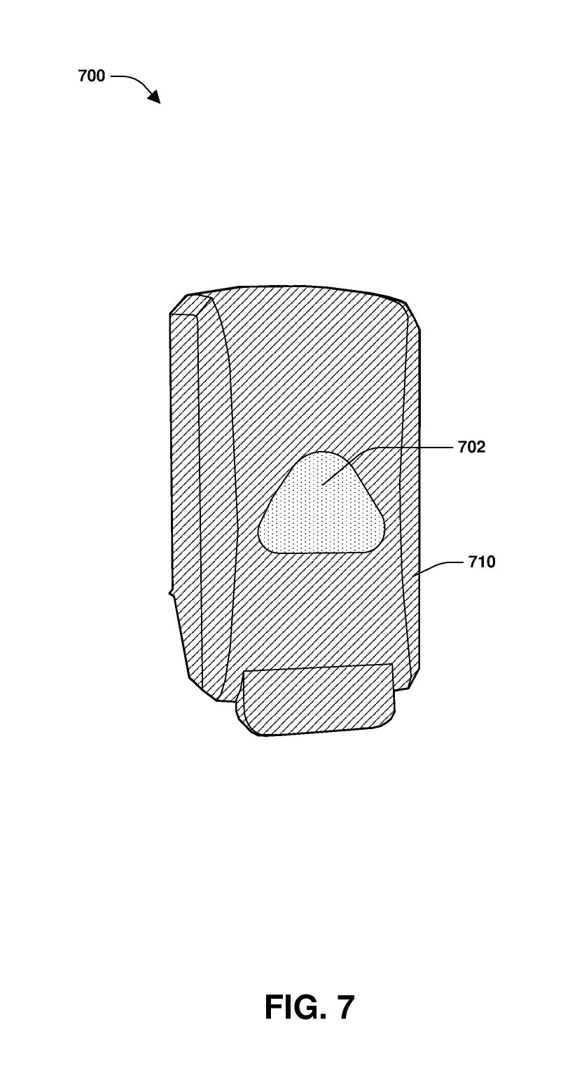

FIG. 7 illustrates a hygiene device housing 700 comprising a triangular aesthetic layer 702. The hygiene device housing 700 comprises a metallic layer 710 overlaying a first portion of the hygiene device housing 700. The first portion may not comprise the triangular aesthetic layer 702.

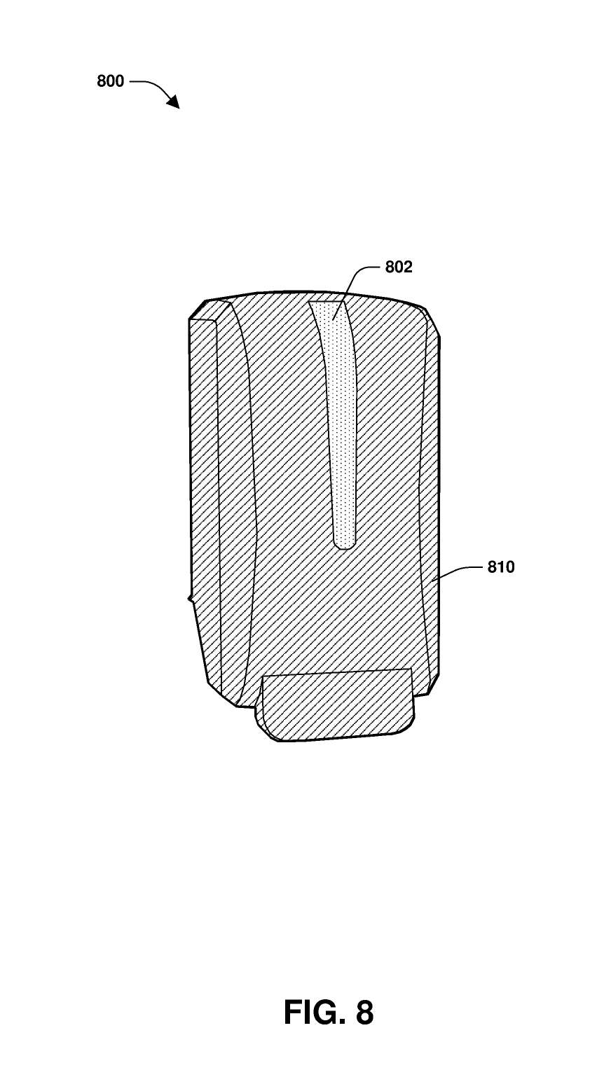

FIG. 8 illustrates a hygiene device housing 800 comprising a central oblong aesthetic layer 802. The hygiene device housing 800 may comprise a metallic layer 810 overlaying a first portion of the hygiene device housing 800. The first portion may not comprise the central oblong aesthetic layer 802.

Although the subject matter has been described in language specific to structural features or methodological acts, it is to be understood that the subject matter defined in the appended claims is not necessarily limited to the specific features or acts described above. Rather, the specific features and acts described above are disclosed as example forms of implementing at least some of the claims.

Many modifications may be made to the instant disclosure without departing from the scope or spirit of the claimed subject matter. Unless specified otherwise, “first,” “second,” or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally to be construed to mean “one or more” unless specified otherwise or clear from context to be directed to a singular form. Also, at least one of A and B or the like generally means A or B or both A and B. Furthermore, to the extent that “includes”, “having”, “has”, “with”, or variants thereof are used in either the detailed description or the claims, such terms are intended to be inclusive in a manner similar to “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method of hygiene device housing formation, comprising:
forming a device housing comprising a shaped in-mold decoration (IMD), the shaped IMD comprising an adhesive layer between an outer layer and an aesthetic layer of the shaped IMD;
depositing a metallic layer over the device housing; and
exposing the device housing to an energy emission to disrupt the adhesive layer to remove the outer layer exposing the aesthetic layer.

2. The method of claim 1, the forming comprising:
placing the shaped IMD within a mold; and
injecting a device housing material into the mold around the shaped IMD.

3. The method of claim 1, the forming comprising:
forming the aesthetic layer;
forming the adhesive layer over the aesthetic layer; and
forming the outer layer over the adhesive layer, the adhesive layer comprising a bond between the aesthetic layer and the outer layer.

4. The method of claim 1, comprising shaping an IMD to form the shaped IMD.

5. The method of claim 4, the shaping comprising cutting the IMD.

6. The method of claim 1, the depositing comprising utilizing physical vapor deposition (PVD) to deposit the metallic layer.

7. The method of claim 1, the depositing comprising depositing an alloy compound as the metallic layer.

8. The method of claim 1, the depositing comprising using vacuum metal deposition to deposit the metallic layer.

9. The method of claim 1, the exposing the device housing comprising exposing the device housing to at least one of:
ultra violet light;
electromagnetic radiation;
an electromagnetic field; or
thermal energy.

10. The method of claim 1, comprising applying a clear coat to the device housing.

11. The method of claim 10, comprising curing the clear coat utilizing ultra violet light.

12. The method of claim 1, comprising forming a strip of a composite material on an edge of the shaped IMD.

13. A method of forming a hygiene device housing, comprising:
shaping an in-mold decoration (IMD) to form a shaped IMD;
forming a device housing comprising the shaped IMD, the shaped IMD comprising an adhesive layer between an outer layer and an aesthetic layer of the shaped IMD;
depositing a metallic layer over the device housing; and
exposing the device housing to an energy emission to disrupt the adhesive layer to remove the outer layer exposing the aesthetic layer and to form the hygiene device housing.

14. The method of claim 13, the forming comprising:
forming the aesthetic layer;
forming the adhesive layer over the aesthetic layer; and
forming the outer layer over the adhesive layer, the adhesive layer comprising a bond between the aesthetic layer and the outer layer.

15. The method of claim 13, the aesthetic layer comprising at least one of a transparent layer, a graphics layer, a logo layer, a text layer, a colored layer, or a shielding layer.

16. The method of claim 13, forming comprising:
placing the shaped IMD within a mold; and
injecting a device housing material into the mold around the shaped IMD.

17. The method of claim 13, the depositing comprising using physical vapor deposition (PVD) to deposit the metallic layer.

18. The method of claim 13, the depositing comprising depositing an alloy compound as the metallic layer.

19. The method of claim 13, the depositing comprising using vacuum metal deposition to deposit the metallic layer.

20. A hygiene device comprising:
a hygiene device housing comprising:
an aesthetic layer comprising at least one of a transparent layer, a graphics layer, a logo layer, a text layer, a colored layer, or a shielding layer; and
a metallic layer formed over a first portion of the hygiene device housing, the first portion not comprising the aesthetic layer, the metallic layer comprising a first top surface along a first side of the hygiene device housing, the aesthetic layer comprising a second top surface along the first side, the first top surface having a first distance from a second side of the hygiene device housing, the second top surface having a second distance from the second side, the first side opposite the second side, the first distance greater than the second distance.
